(19) United States
(12) Patent Application Publication
(10) Pub. No.: US 2009/0095891 A1
(43) Pub. Date: Apr. 16, 2009

(54) Image Sensor and Manufacturing Method Thereof

(76) Inventor: Seung Ryong PARK, Seoul (KR)

Correspondence Address: THE LAW OFFICES OF ANDREW D. FORTNEY, PH.D., P.C., 401 W FALLBROOK AVE STE 204, FRESNO, CA, 93711-5835, US

(21) Appl. No.: 12/244,694

(22) Filed: Oct. 2, 2008

(30) Foreign Application Priority Data
Oct. 15, 2007 (KR) 10-2007-0103371

(51) Int. Cl. H01L 31/0232

(52) U.S. Cl. 250/226; 438/29; 257/E31.127

(57) ABSTRACT

Disclosed is an image sensor. The image sensor includes a semiconductor substrate, a photodiode in the semiconductor substrate in each unit pixel, a lower color filter on each photodiode, a metal interconnection layer on or over the semiconductor substrate and the lower color filter, and a microlens on or over the metal interconnection layer corresponding to a particular lower color filter.

The present application claims priority under 35 U.S.C. 119 to Korean Patent Application No. 10-2007-0103371 (filed on Oct. 15, 2007), which is hereby incorporated herein by reference in its entirety.

### BACKGROUND

Embodiments of the invention relate to an image sensor and a manufacturing method thereof.

An image sensor is a semiconductor device for converting an optical image into electric signals. Image sensors generally include CCD (charge coupled device) image sensors and CMOS (Complementary Metal Oxide Silicon) image sensors. The CIS (CMOS image sensor) includes a photodiode and at least one MOS transistor in each unit pixel, and sequentially detects and/or processes an electric signal of each unit pixel in a switching mode to realize an image.

As design rules are gradually reduced in the CMOS image sensor design, the size of the unit pixel is also reduced, and photosensitivity may also be reduced. In order to increase the photosensitivity, a micro lens is formed on or over a color filter corresponding to the unit pixel. However, although the micro lens is formed, the photosensitivity may be reduced due to optical limitation(s) and diffraction and scattering in the device.

### SUMMARY

Embodiments of the invention provide an image sensor capable of improving the photosensitivity by forming a color filter proximate to a photodiode, and a manufacturing method thereof.

An image sensor according to various embodiments includes a semiconductor substrate having a plurality of unit pixels, a photodiode on or in the semiconductor substrate in each unit pixel, a lower color filter on or over each photodiode, a metal interconnection layer on or over the semiconductor substrate, and a microlens on or over the metal interconnection layer, corresponding to each lower color filter. In certain embodiments, the metal interconnection layer is located adjacent to the lower color filter, preferably over a transistor region of the unit pixel. Similarly, in certain embodiments, the microlens is located adjacent to the metal interconnection layer, preferably over the lower color filter in the unit pixel.

A method for manufacturing an image sensor according to various embodiments includes the steps of forming a photodiode on a semiconductor substrate in each unit pixel, forming a lower color filter on each photodiode, forming a metal interconnection layer on or over the semiconductor substrate, and forming a microlens on or over the metal interconnection layer corresponding to each lower color filter. As for the image sensor, the metal interconnection layer may be located adjacent to the lower color filter, preferably over a transistor region of the unit pixel, and in certain embodiments, the microlens is located adjacent to the metal interconnection layer, preferably over the lower color filter in the unit pixel.

### BRIEF DESCRIPTION OF THE DRAWINGS

FIGS. 1 to 6 are cross-sectional views illustrating various stages in an exemplary procedure for manufacturing an image sensor according to various embodiments.

### DETAILED DESCRIPTION OF THE EMBODIMENTS

Hereinafter, an image sensor and a manufacturing method thereof according to embodiments of the invention will be described with reference to the accompanying drawings.

FIG. 6 is a cross-sectional view illustrating an exemplary image sensor according to an embodiment.

Referring to FIG. 6, lower color filters 31, 32, 33 are disposed on a semiconductor substrate 10 including photodiodes 20 disposed in each unit pixel. The photodiodes 20, which receive light to generate photocharges, and CMOS circuits (not shown), which are electrically connected to the photodiodes 20 to convert the received photocharges into electric signals, may be formed on the semiconductor substrate 10 in each unit pixel.

The lower color filters (or a lower color filter layer) include a first color filter 31, a second color filter 32 and a third color filter 33. The first to third color filters 31 to 33 are on a corresponding photodiode 20 in each unit pixel. For example, the color filter 31 may have a red color, the second color filter 32 may have a green color, and the third color filter 33 may have a blue color. Alternatively, the color filter 31 may have a yellow color, the second color filter 32 may have a cyan color, and the third color filter 33 may have a magenta color. Typically, the color filters 31-33 comprise a colored dye, mixed in a resist binder.

The first to third color filters 31 to 33 may each have an area larger than that of the corresponding photodiodes 20, in order to cover the photodiodes 20, respectively. Further, the first to third color filters 31 to 33 may be spaced apart from each other, and may be on a thin (e.g., 20-500 Angstroms) transparent layer (e.g., silicon dioxide that is, in turn, on each photodiode 20.

Since the first to third color filters 31 to 33 are on the photodiodes 20, light is directly incident into the corresponding photodiode 20 through the first to third color filters 31 to 33. Thus, crosstalk can be prevented and the photosensitivity can be improved. Further, because the first to third color filters 31 to 33 cover photodiodes 20, a fill factor of the image sensor can be improved.

A metal interconnection layer is disposed on or over the semiconductor substrate 10, including (but adjacent to or not covering) the lower color filters 31-33. The image sensor may include one or more metal interconnection layers 50 and one or more interlayer dielectric layers 40. Each metal interconnection layer 50 may comprise aluminum or an aluminum alloy (e.g., Al with up to 4 wt. % Cu, up to 2 wt. % Ti, and/or up to 1 wt. % Si), on conventional adhesion and/or barrier layers (e.g., Ti and/or TiN, such as a TiN-on-Ti bilayer), and/or covered by conventional adhesion, barrier, hillock suppression, and/or antireflective layers (e.g., Ti, TiN, WN, TiW alloy, or a combination thereof, such as a TiN-on-Ti bilayer or a TiW-on-Ti bilayer). Each interlayer dielectric layer 40 may comprise a lowermost, conformal etch stop layer (e.g., silicon nitride), a conformal buffer and/or gap-fill layer (e.g., silicon-rich oxide [SRO], TEOS [e.g., a silicon oxide formed by CVD from tetraethyl orthosilicate and oxygen], an undoped silicate glass [USG] or a combination thereof), and a bulk dielectric layer (e.g., one or more silicon oxide layers doped with boron and/or phosphorous [BSG, PSG and/or BPSG]). Alternatively, the bulk dielectric layer may comprise a low-k dielectric, such as a fluorosilicate glass (FSG), silicon oxycarbide (SiOC) or hydrogenated silicon oxycarbide (SiOCH), any of which may comprise upper and lower low-k dielectric layers above and below an intermediate etch stop layer (e.g., silicon nitride). Each interlayer dielectric layer 40 may further comprise a capping layer, e.g., of TEOS, USG, a plasma silane (e.g., silicon dioxide formed by plasma-assisted CVD of silicon dioxide from silane and oxygen), or a combination thereof, such as a bilayer of plasma silane on USG or TEOS, or a bilayer of USG on TEOS. An uppermost dielectric layer 40 may comprise a conventional passivation layer (e.g., silicon dioxide, silicon nitride, silicon oxynitride, or a combination thereof, such as silicon nitride on silicon dioxide).

In addition, an upper color filter layer can be disposed on or over the uppermost metal interconnection layer 50 (e.g., on the uppermost dielectric layer 40). The upper color filter layer can comprise individual color filters (e.g., 61, 62 63) corresponding to the lower color filters 31, 32 33 disposed in each unit pixel. In detail, the upper color filter layer may include a first color filter 61, a second color filter 62 and a third color filter 63 corresponding to the first to third color filters 31 to 33, respectively. For example, the color filter 61 has a red color, the second color filter 62 has a green color, and the third color filter 63 has a blue color. Alternatively, the color filter 61 may have a yellow color, the second color filter 62 may have a cyan color, and the third color filter 63 may have a magenta color. Typically, like the first to third color filters 31 to 33, the color filters 61-63 generally comprise a colored dye, mixed in a resist binder.

Microlenses 70 are disposed on the metal interconnection layer in each unit pixel. Each microlens 70 has a dome or convex shape to guide light toward the photodiode 20. Typically, the microlenses 70 generally comprise a reflowed resist, or a low temperature oxide (LTO). In the latter case, the LTO may comprise silicon dioxide and be formed by plasma enhanced chemical vapor deposition (PECVD) from one or more silicon dioxide precursors (e.g., a silicon source such as silane gas or tetraethyl orthosilicate, and an oxygen source such as dioxygen and/or ozone) at a temperature of 250° C. or less.

According to the exemplary image sensors, the lower color filter on the photodiodes improves the photosensitivity in each unit pixel. Furthermore, the lower color filter and the upper color filter are each disposed on or over the photodiodes to prevent crosstalk. In particular, even if light passing through the upper color filter is diffracted or scattered by the metal interconnection layer, since the lower color filter can also filter any stray light that would otherwise impinge on the underlying photodiode, crosstalk can be prevented.

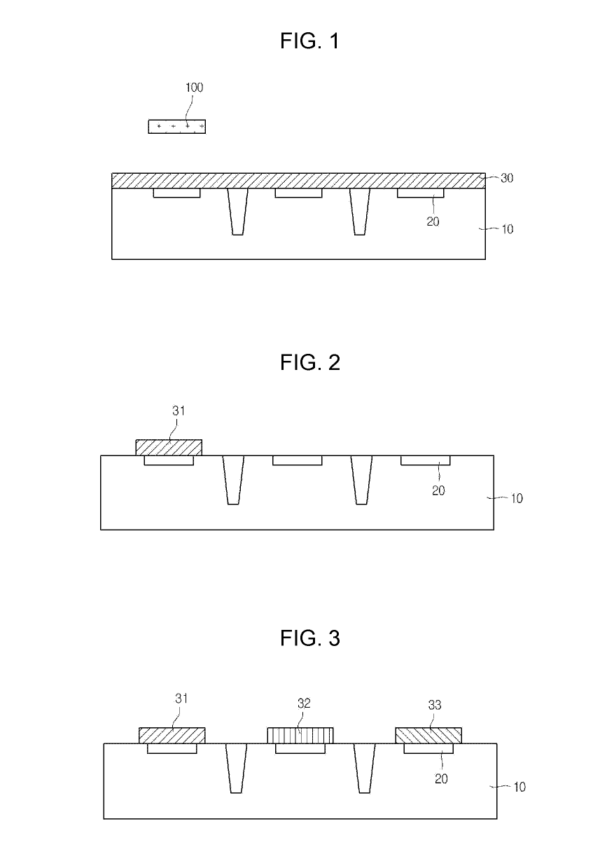

Hereinafter, an exemplary manufacturing procedure of the image sensor according to various embodiments will be described with reference to FIGS. 1 to 6.

Referring to FIG. 1, a first color filter layer 30 is formed on the semiconductor substrate 10 including the photodiodes 20, generally by spin-coating a resist solution containing a dye therein. Prior to forming the first color filter layer 30, an isolation layer defining an active area and a field area (shown having sloped sidewalls) is formed in the semiconductor substrate 10. Further, the photodiodes 20, which receive light to generate photocharges, and the CMOS circuits (not shown) connected to each photodiode 20 to convert the received photocharges into electric signals, may be formed on the active area in each unit pixel.

Referring to FIGS. 1 and 2, the first color filter layer 30 is formed on a predetermined photodiode 20 corresponding to the color of light to be detected by that particular unit pixel. The first color filter layer 30 is formed on the semiconductor substrate 10 using a material, such as a photoresist and one or more pigments or a photoresist and one or more dyes, applied or deposited by a spin coating process or the like. Next, a pattern mask 100 is used in a photolithography process to provide the first color filter layer 31 with an area larger than that of the photodiode 20. For example, the first color filter layer 30 is subject to an exposure and development process using the pattern mask 100, so that the first color filter 31 is formed on the photodiode 20. The first color filter 31 has an area larger than that of the photodiode 20 to sufficiently cover the photodiode 20.

Referring to FIG. 3, remaining filters 32 and 33 in the lower color filter layer are formed on the corresponding photodiodes 20 in each unit pixel. The second and third filters 32 and 33 are formed in the same manner as that of the first color filter 31. Further, first to third color filters 31 to 33 are spaced apart from each other. Thus, the first to third color filters 31 to 33 are formed on the photodiodes 20 in each unit pixel, respectively, thereby filtering colors from incident or scattered light. For example, the color filter 31 has a red color, the second color filter 32 has a green color, and the third color filter 33 has a blue color.

The first to third color filters 31 to 33 are formed on the photodiodes 20, so that light can be directly incident into the corresponding photodiode 20 through the first to third color filters 31 to 33. Further, the first to third color filters 31 to 33 are spaced apart from each other, so that any limitations in forming sidewalls of the color filters can be reduced.

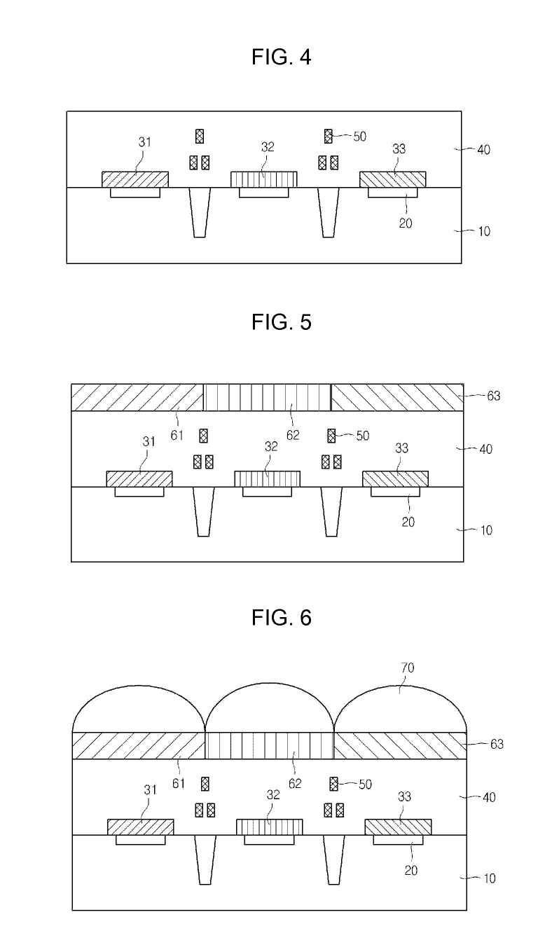

Referring to FIG. 4, a metal interconnection layer is formed on or over the semiconductor substrate 10, but adjacent to (i.e., not over) the first to third color filters 31 to 33. The metal interconnection layer may be formed on a first one of plural interlayer dielectric layers 40. Thus, the interlayer dielectric layer 40 may have plural layers. For example, each of the plural interlayer dielectric layers 40 may include a nitride layer and/or an oxide layer.

A plurality of metal interconnections 50 may be formed alternately with the individual interlayer dielectric layers 40. The metal interconnections 50 are configured such that the metal interconnections 50 do not block the light incident onto the photodiodes 20.

Referring to FIG. 5, the upper color filter layer including the first to third color filters 61 to 63 is formed on or over the metal interconnection layer and/or the interlayer dielectric layer 40. The first to third color filters 61 to 63 on/over the metal interconnection layer 50 and/or the interlayer dielectric layer 40 can be formed in the same manner as that of the first to third color filters 31 to 33.

For example, a first upper color filter layer (not shown) may be formed on the uppermost interlayer dielectric layer, an upper mask pattern (not shown) is placed over the first upper color filter layer, and then an exposure and development process is performed to form the first upper color filter (e.g., 61). At this time, the upper mask pattern has a size such that the first upper color filter (e.g., 61) has an area corresponding to each unit pixel including the photodiode 20. In detail, the upper mask pattern may be larger than the lower mask pattern 100 for forming the lower color filter.

The first color filter 61 is formed over the first color filter 31, the second color filter 62 is formed over the second color filter 32, and the third color filter 63 is formed over the third color filter 33.

The first to third color filters 61 to 63 are formed above the first to third color filters 31 to 33 in each unit pixel, thereby filtering colors for that unit pixel from incident light. Generally, the first to third upper color filters 61 to 63 have the same color as the first to third lower color filters 31 to 33. For example, the color filter 61 may have a red color, the second color filter 62 may have a green color, and the third color filter 63 may have a blue color.

Thus, light is incident onto the corresponding photodiode 20 through at least one of the first to third color filters 61 to 63 and the first to third color filters 31 to 33. In particular, even if the light passing through the first color filter 61 is diffracted or scattered and thus the progress direction of the light is changed, the light that would otherwise impinge on a photodiode in a different unit pixel can be blocked by the second and/or third color filters 32 and 33, so that crosstalk can be fundamentally prevented.

Although not shown in the drawings, a planarization layer may be formed on the semiconductor substrate 10 including the upper color filter layer. The microlenses 70 to be formed through a subsequent process should be formed on a planarized surface. Thus, since a step difference that may be caused by the individual upper color filters 61-63 having different heights should be removed, the planarization layer can be formed on the upper color filter layer.

Referring to FIG. 6, the microlenses 70 are formed on the upper color filter. In order to form the microlenses 70, a silicon oxide layer having a high light transmittance, or photosensitive photoresist, is coated on the planarization layer or the upper color filter layer, and then a patterning process is performed. Next, when the microlenses 70 comprise a photoresist, an angular lens patterns may be formed on the first to third color filters 61 to 63 corresponding to the photodiodes 20 in each unit pixel. Then, the lens patterns are subject to a reflow process, so that the microlenses 70 having a dome shape are formed in each unit pixel. One microlens 70 is formed in each unit pixel, thereby guiding light toward the photodiode 20 of the semiconductor substrate 10 disposed below the microlens 70.

According to the exemplary manufacturing method of the present image sensor, the lower color filters are formed on the photodiodes in each unit pixel, respectively. Thus, light passing through the lower color filters is directly incident into a corresponding photodiode, so that crosstalk can be prevented and the photosensitivity of the image sensor can be improved.

Further, the upper color filters are formed on or over the lower color filters in each unit pixel, so that the photosensitivity of the image sensor can be further improved. In detail, even if light passing through a first upper color filter progresses toward the second and/or third lower color filters (formed below the upper color filter) due to refraction and reflection in a device, the second and third lower color filters can block the light, so that crosstalk can be prevented and photosensitivity can be improved.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor comprising:
a semiconductor substrate;
a photodiode on the semiconductor substrate in each of a plurality of unit pixels;
a lower color filter on each of the photodiodes;
a metal interconnection layer on or over the semiconductor substrate; and
microlenses on or over the metal interconnection layer, each microlens corresponding to one of the lower color filters.

2. The image sensor as claimed in claim 1, wherein each lower color filter has an area larger than an area of the corresponding photodiode.

3. The image sensor as claimed in claim 1, further comprising dielectric layers above and below the metal interconnection layer.

4. The image sensor as claimed in claim 3, wherein the metal interconnection layer comprises lower and upper metal interconnection layers and an intermediate dielectric layer therebetween.

5. The image sensor as claimed in claim 3, further comprising an upper color filter on the dielectric layer above the metal interconnection layer.

6. The image sensor as claimed in claim 4, wherein the lower color filter has a color identical to the corresponding upper color filter.

7. The image sensor as claimed in claim 1, wherein the lower color filter has a color selected from the group consisting of red, green and blue colors.

8. The image sensor as claimed in claim 1, wherein the lower color filters comprise a red color filter, a green color filter, and a blue color filter.

9. The image sensor as claimed in claim 1, wherein the metal interconnection layer is adjacent to, and not over, the lower color filter.

10. The image sensor as claimed in claim 1, wherein the microlenses are generally between adjacent metal interconnection layers.

11. A method for manufacturing an image sensor, the method comprising the steps of:
forming photodiodes on a semiconductor substrate having a plurality of unit pixels;
forming a lower color filter on or over each of the photodiodes;
forming a metal interconnection layer on or over the semiconductor substrate; and
forming a microlens on or over the metal interconnection layer corresponding to each lower color filter.

12. The method as claimed in claim 11, wherein the step of forming the lower color filter includes the steps of:
forming a lower color filter layer on or over the semiconductor substrate including the photodiodes; and
patterning the lower color filter layer to have an area larger than a corresponding area of the photodiode.

13. The method as claimed in claim 12, wherein patterning the lower color filter layer comprises performing an exposure and development process on the lower color filter layer using a lower mask pattern.

14. The method as claimed in claim 11, further comprising forming dielectric layers above and below the metal interconnection layer.

15. The method as claimed in claim 14, further comprising forming an upper color filter on or above the dielectric layer above the metal interconnection layer.

16. The method as claimed in claim 15, wherein the lower color filter has a color identical to the upper color filter.

17. The method as claimed in claim 15, wherein the step of forming the upper color filter includes the steps of:
forming an upper color filter layer on the metal interconnection layer; and
patterning the upper color filter layer to form an upper color filter in each unit pixel including the photodiode.

18. The method as claimed in claim 17, wherein patterning the upper color filter layer comprises performing an exposure and development process on the upper color filter layer using an upper mask pattern.

19. The method as claimed in claim 11, wherein the lower color filter has a color selected from the group consisting of red, green and blue colors.

20. The method as claimed in claim 19, wherein the lower color filters comprise a red color filter, a green color filter, and a blue color filter.
